(19) United States
(12) Patent Application Publication
(10) Pub. No.: US 2026/0282265 A1
(43) Pub. Date: Sep. 17, 2026

(54) RAINBOW BRIDGE FOR DAISY CHAINING POWER MANAGEMENT COMPONENTS

(71) Applicant: Quanta Computer Inc., Taoyuan City (TW)

(72) Inventors: Kuo-Chan HSU, Taoyuan City (TW); Yun-Teng SHIH, Taoyuan City (TW); Cheng-Jhen YANG, Taoyuan City (TW)

(21) Appl. No.: 19/080,407

(22) Filed: Mar. 14, 2025

(51) Int. Cl. H05K 7/14; H05K 1/02

(52) U.S. Cl. CPC H05K 7/1492; H05K 1/0257; H05K 1/0262; H05K 7/1498; H05K 2201/10015; H05K 2201/10022; H05K 2201/1003; H05K 2201/10181

(57) ABSTRACT

A power management component that allows daisy chaining of parallel power management devices is disclosed. The power management component has a first side including input pins connectable to the power source. A second side parallel to the first side includes an output pin connectable to a power rail on a circuit board. The power management component has a pair of sides perpendicular to the first side each with at least one identical signal pin. The identical signal pins are connectable to a rainbow bridge interconnection between the power management component and another power management component to avoid routing signal lines over the power source or output source.

### TECHNICAL FIELD

The present invention relates generally to power management components, and more specifically, to a rainbow bridge for interconnecting signal pins on power management components that allows efficient daisy chaining of power management components for high power applications.

### BACKGROUND

Servers are employed in large numbers for high demand applications, such as network based systems or data centers. The emergence of cloud computing applications has increased the demand for data centers. Data centers have numerous servers that store data and run applications accessed by remotely connected, computer device users. A typical data center has physical rack structures with attendant power and communication connections. Each rack may hold multiple application servers and storage servers in different shelves. A server structure may be a compute tray that may be held in the shelves. A rack may include a power shelf or shelves that hold multiple power supply units to provide centralized power to other components in the rack such as the compute trays. The individual compute trays generally include hardware components such as processors, memory devices, network interface cards, power supplies, and other specialized hardware on one or more printed circuit boards. Each of the servers generally includes a baseboard management controller that manages the operation of the server and communicates operational data to a central management station that manages the servers of the rack.

For recent server applications, smaller printed circuit board size and higher power density are the major goals for designers. Higher power densities require specialized power management integrated circuit devices to protect components on the printed circuit boards. Currently there are two major kinds of power management integrated circuit components that may be installed on a printed circuit board to perform power management functions. These power management components include an E-fuse (e.g. a hot swap circuit), which limits current, and a Smart Power Stage (SPS) device, which is an integrated current modulation and protection device.

An E-fuse mainly controls a hot plug connection of a compute tray to a live power shelf. Thus, an E-fuse determines if input power from the power shelves may be safely transferred into a compute tray in a server rack system. The E-fuse continuously monitors the voltage and current from the power shelves. The startup time and voltage slew rate can be controlled to ensure there is no large inrush current to the compute tray from the power shelves when the compute tray is connected. If any fault is detected, the E-fuse will cut off the connection between the compute tray and power shelves, thus protecting the components on the compute tray from damage from the fault. As the power demand for compute trays grows, two or more synchronized E-fuses operating in parallel may be required to share high current stress from the power shelves.

SPS devices play the role of converting an output from a medium power supply to relatively low voltages for devices such as CPUs, GPUs, and ASICs in a compute tray. A buck converter topology is generally adopted for the SPS device in such applications. To share high current stress and to improve the performance, a multiphase control scheme is usually implemented. Each SPS device may be viewed as a buck converter while an external SPS controller will manipulate and control multiple SPS devices that are assigned for different phases. For recent Vcore applications, a 16-phase or even a 32-phase SPS device might be needed to support high power GPUs or ASICs.

FIG. 1A is diagram of a prior art circuit board 10 that includes E-fuses 12 and 14 that are wired in parallel to share high current stress. A high voltage/high power plane 20 is connected to power supplies on a power shelf. The power plane 20 is connected to power input pins 22 on the E-fuses 12 and 14. A set of power output pins 24 from each of the E-fuses 12 and 14 supply power to a voltage rail 30. Thus, voltage is provided from the power plane 20 through the voltage rail 30 to components such as those on a printed circuit board. In the parallel arrangement of the E-fuses 12 and 14, there are several signal routing interconnections between the E-fuses 12 and 14 and other E-fuses that are wired in parallel. For example, a power good (PG) signal line 32 and an over-temperature (Vtemp) signal line 34 are coupled to each of the E-fuses 12 and 14. The signal lines 32 and 34 are routed under the power plane 20. Other signal lines such as an enable (EN) signal line 36, soft-start setting (dvdt) line 38, and a current reference signal (IREF) line 40 must be connected between respective pins on the E-fuses 12 and 14. As shown in FIG. 1A, due to the pin placement on the E-fuses 12 and 14, the signal lines 36, 38, and 40 must be routed under the voltage rail 30.

FIG. 1B shows a diagram of a prior art power management system on a compute tray circuit board 50 that includes SPS chips 52 and 54. A high voltage/high power plane 60 is connected to power supplies on a power shelf. The power plane 60 is connected to voltage input pins 62 on each of the SPS chips 52 and 54. A ground strip 64 is connected to different ground input pins 66 on each of the SPS chips 52 and 54. A set of voltage output pins 68 on each of the SPS chips 52 and 54 output a pulsed voltage signal that is routed to respective inductor/capacitor circuits 70 to provide a regulated voltage to power components on the circuit board.

A set of control signals are received by a set of control signal input pins on the SPS chips 52 and 54. An SPS controller sends a PWM signal to a PWM control pin via separate control lines 72 for each of the SPS chips 52 and 54. The PWM signal controls the pulsed voltage output from the voltage outputs of the SPS chips 52 and 54. Additional input pins allow transmission of data signals of operational data or receiving command signals for the SPS chips 52 and 54. For example, a sensing current signal (IOUT) is sent via sensing current (IOUT) signal lines 74 from each of the SPS chips 52 and 54. An enable (EN) signal line 76 allows an external signal to enable the SPS chips 52 and 54. A temperature monitoring (TMON) signal line 78 is connected to respective pins on each of the SPS chips 52 and 54 to indicate the over temperature fault by the SPS chips 52 and 54. The signal lines 74, 76, and 78 to these pins must be routed under the power plane 60.

As shown in the power management arrangements in both FIG. 1A and 1B, the interconnections for different control and data signals between the power management components (E-fuses or SPS chips) are relatively complicated. These routing lines need several vias to travel across the high voltage/power plane to connect with each other. Other routing lines need vias to travel under the voltage rail 30 for the E-fuse arrangement in FIG. 1A. When considering circuit performance, circuit board area limitation, and circuit board cost, these complex layouts lead to drawbacks and inherent defects that degrade power supply performance for printed circuit boards.

For example, the input path area on a circuit board for such signal lines, the copper fill and current flow pathways must be routed around obstructions such as the high voltage/high power plane 20 and the voltage rail 30 in FIG. 1A. This mandates a perpendicular turn in the power plane to interface with the power management devices. These turns degrade the performance of the power circuit. Jagged, incomplete and indirect power planes lead to worse power flow characteristics and low heat dissipation rate. In addition, to synchronize the parallel power management components, several signals must be interconnected between devices, resulting in complicated routings that need vias and several layers to get successful connection. A large number of vias or advanced via designs are required to make the interconnections possible if the printed circuit board has limited layers. Excessive numbers of vias could lead to low noise immunity and crosstalk between routed signals. Circuit precision may be reduced and subsequently lead to higher risk of errors in a compute tray. Holes on the internal ground copper fill caused by these vias will also impair the current return path and further degrade circuit performance. To mitigate the above impacts, circuit board designers generally need complicated assessments for layout routing and placement, a sufficiently large circuit board area, and more layers as well as advanced via techniques for power management components. These solutions are costly and still result in the potential for signal noise as well as reduction of power efficiency. Failure to carefully consider any of these factors could lead to suboptimal performance or even circuit failure.

Thus, there is a need for a bridge architecture that allows for the simplification of signal connections between power management components. There is another need for a design for a power management component that enables direct top/bottom layout placement for power inputs and outputs, thereby reducing the required printed circuit board area for power management components. There is another need for a power management design that has signal pins positioned to eliminate any vias for the interconnections between devices, making layout routings and copper fills clean and direct.

### SUMMARY

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a power management component for receiving power from a power source and performing a power management function is disclosed. The power management component includes a first side having an input pin connectable to the power source and a second side, parallel to the first side, having an output pin connectable to a power rail on a circuit board. The power management component includes a power management function circuit coupled between the input pin and the output pin. The power management component includes a pair of sides perpendicular to the first side. Each of the pair of sides has at least one identical signal pin that that may each receive an input signal that may be transmitted by the other identical signal pin or transmit a signal from the power management component.

A further implementation of the example power management component is where the power management component is an E-fuse. The power management function circuit cuts off power to the output pin when a fault is detected in the power source. Another implementation is where the at least one identical signal pin is one of a power good signal pin, an over-temperature signal pin, an enable signal pin, a soft start setting pin, or a current reference signal pin. Another implementation is where the power management component is a smart power stage (SPS) device. The power management function circuit is a buck converter outputting a pulsed voltage signal. Another implementation is where the at least one identical signal pin is one of a sensed current signal pin, an enable signal pin, or a sensed temperature pin. Another implementation is where the at least one identical signal pin receives a pulse width modulation (PWM) signal driving the buck converter. Another implementation is where the example power management component includes a phase shift input pin connectable to a resistor. A value of the resistor determines a phase of the PWM signal provided to the buck converter. Another implementation is where the at least one identical signal pin is one of a plurality of identical signal pins, each connectable to a rainbow bridge interconnection coupling each of the plurality of signal pins to a corresponding signal pin of another power management device. The another power management component has an input pin connectable to the power supply.

According to certain aspects of the present disclosure, a printed circuit board is disclosed. The printed circuit board includes a power plane connectable to a power shelf having a power supply. A first power management component has: a first side including an input pin connectable to the power plane; a second side parallel to the first side including an output pin; a power management function circuit coupled between the input pin and the output pin; and a pair of sides perpendicular to the first side. Each of the pair of sides have at least one identical signal pin. A second power management component has: a first side including an input pin connectable to the power plane; a second side parallel to the first side including an output pin; a power management function circuit coupled between the input pin and the output pin; and a pair of sides perpendicular to the first side. Each of the pair of sides include at least one identical signal pin. A first rainbow bridge directly couples one of the identical signal pins of the first power management component to one of the identical signal pins of the second power management component.

A further implementation of the example printed circuit board is where the power plane has a substantially rectangular shape. Another implementation is where the first and second power management components are E-fuses. The power management function circuit cuts off power to the output pin when a fault is detected in the power plane. Another implementation is where the at least one identical signal pin is one of a power good signal pin, an over-temperature signal pin, an enable signal pin, a soft start setting pin, or a current reference signal pin. Another implementation is where the first and second power management components are smart power stage (SPS) devices. The power management function circuit is a buck converter outputting a pulsed voltage signal. Another implementation is where the at least one identical signal pin is one of a sensed current signal pin, an enable signal pin, or a sensed temperature pin. Another implementation is where the example printed circuit board includes an inductor and capacitor regulated voltage circuit coupled to the output pins of the first and second power management components to provide regulated voltage to components on the printed circuit board. Another implementation is where the example printed circuit board includes a power management controller including a pulse width modulation (PWM) signal output coupled to the identical signal pin of the first power management component. The PWM signal drives the buck converters of the first and second power management components. Another implementation is where the example printed circuit board includes a first resistor coupled to a phase shift pin on the first power management component. A value of the first resistor determines a first phase of the PWM signal provided to the buck converter of the first power management component. A second resistor is coupled to a phase shift pin on the second power management component. A value of the second resistor determines a second phase of the PWM signal provided to the buck converter of the second power management component. Another implementation is where the example printed circuit board includes a third power management component having: a first side including an input pin connectable to the power plane; a second side parallel to the first side including an output pin; a power management function circuit coupled between the input pin and the output pin; and a pair of sides perpendicular to the first side. Each of the pair of sides includes at least one identical signal pin. A second rainbow bridge directly couples one of the identical signal pins of the second power management component to one of the identical signal pins of the third power management component.

According to certain aspects of the present disclosure, a smart power stage (SPS) device is disclosed. The SPS chip includes an integrated circuit package having a first side, an opposite second side, and a pair of sides perpendicular to the first side. A voltage input pin is located on the first side. The voltage input pin is connectable to a power source. An output pin is located on the second side. A buck converter is coupled between the voltage input pin and the output pin to provide a pulsed voltage signal on the output pin. A first pulse width modulation (PWM) signal pin is located on one of the pair of sides. A second PWM signal pin is located on the other of the pair of sides. A PWM signal received on the first PWM signal pin is output by the second PWM signal pin and drives the buck converter.

Another implementation of the example SPS device includes a phase shift pin connectable to a resistor to shift the phase of the pulsed voltage signal provided by the buck converter.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1A is a circuit board layout diagram of a prior art power management system with parallel E-fuses;

FIG. 1B is a circuit board layout diagram of a prior art power management system of parallel SPS device;.

FIG. 2 is a circuit diagram of example E-fuses connected to an example rainbow bridge, according to certain aspects of the present disclosure;

FIG. 3 is a circuit board layout diagram of the arrangement in FIG. 2 with the example E-fuses, according to certain aspects of the present disclosure;

FIG. 4 is a circuit diagram of example SPS devices using an example rainbow bridge, according to certain aspects of the present disclosure;

FIG. 5 is a circuit board layout diagram of the arrangement in FIG. 4 with the example SPS devices, according to certain aspects of the present disclosure;

FIG. 6 is a circuit diagram of an example SPS device that may be programmed by a common PWM signal for controlling a phased voltage output, according to certain aspects of the present disclosure;

FIG. 7 is a table of example resistor values to set the phase of a voltage output from an SPS device, according to certain aspects of the present disclosure;

FIG. 8 is circuit board layout diagram of a power management system with four example SPS devices in FIG. 6 providing four phase voltage output, according to certain aspects of the present disclosure; and

FIG. 9 is a diagram of the control signals to the different SPS devices in FIG. 8 for supplying power at four different phases to a circuit board, according to certain aspects of the present disclosure.

### DETAILED DESCRIPTION

The disclosure is directed to power management components or devices with matching signal pins on opposite sides. Power management devices or components perform various power management functions by receiving power from a power plane and routing the power to a printed circuit board. Example power management components include E-fuses that protect against faults in the power supply and SPS devices that provide regulated power to the circuit board. The example power management component has an integrated circuit package with opposite sides having identical matching signal pins. The identical signal pins may either receive an input data or command signal that may be transmitted by the other identical signal pin or transmit an output data or command signal from the power management component. The matching signal pins on opposite sides of the power management component allow the use of a rainbow bridge with multiple interconnectors that may be installed between the power management components. The power management components are arranged in parallel to each other to allow distribution of power load. Power input pins are positioned on a side perpendicular to the sides with the matching signal pins. Power output pins are positioned on an opposite side perpendicular to the sides with the matching signal pins. Thus, a power plane may be directly connected to the side of each of the parallel power management components without interfering with interconnections between the signal pins. The rainbow bridge design not only enables direct top/bottom layout placement of the power plane, thereby reducing the required circuit board area by half, but also eliminates all the vias needed for the interconnections between the power management devices, thereby making layout routings and copper fills on the circuit board clean and direct. By incorporating a daisy-chained structure for the power management components, circuit board designs with better power flow performance, smaller printed circuit board size as well as lower printed circuit board cost may be achieved. In SPS based power management devices, an example PWM control scheme allows efficient phased power supply by using only a single PWM control line.

Various embodiments are described with reference to the attached figures, where like reference numerals are used throughout the figures to designate similar or equivalent elements. Each reference numeral identifies the figure in which the reference numeral first appears, based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

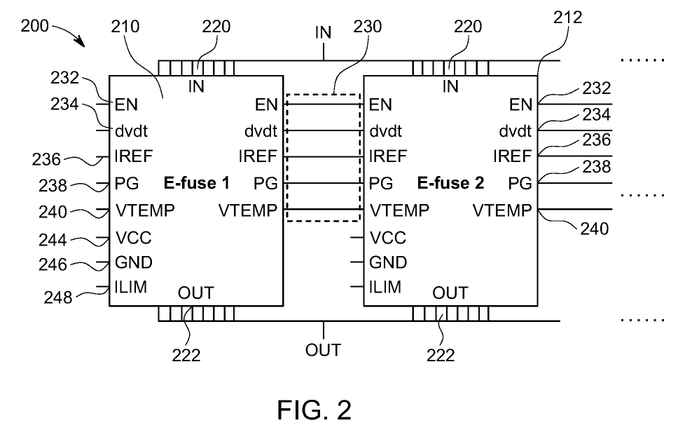

FIG. 2 shows a circuit diagram of a power management assembly 200 that includes two or more power management components to distribute the power load to components on a circuit board. In this example, the power management components are E-fuses 210 and 212 arranged in parallel on a circuit board. In this example, the parallel arrangement of the E-fuses 210 and 212 allows protection for higher power systems as more E-fuses may be used to distribute the power load. A high voltage/high power source is connected to power supplies on a power shelf. The power source is connected to voltage input pins 220 on the E-fuses 210 and 212. Voltage output pins 222 from each of the E-fuses 210 and 212 supply power to a voltage output that supplies voltage to components on the printed circuit board.

In the parallel arrangement of the E-fuses 210 and 212, various identical signal pins allow signal routing interconnections between the E-fuses 210 and 212 and any other E-fuses that are wired in parallel. The identical signal pins may each receive an input data or command signal that may be transmitted by the other identical signal pin or transmit an output data or command signal from the respective E-fuse 210 or 212. This allows the E-fuses 210 and 212 to be daisy chained together. An example rainbow bridge 230 includes interconnections that couple the signal input pins of the E-fuses 210 and 212. Thus, each of the E-fuses 210 and 212 include an enable (EN) signal pin 232, a soft-start setting (dvdt) pin 234, a current reference signal (IREF) pin 236, a power good (PG) signal pin 238, and an over-temperature (Vtemp) signal pin 240. In this example, the enable signal pin 232 receives a control signal to activate the E-fuse. The soft-start time for the output of the E-fuse can be configured through (dvdt) soft-start setting pin 234. The PG signal on the PG signal pin 238 will indicate whether the E-fuses reaches the output voltage that may be set or may be within acceptable parameters. The current reference signal pin 236 receives a signal that configures the current value for each E-fuse to follow. The over-temperature signal pin 240 indicates the temperature value fault condition when an over-temperature condition for the E-fuse has occurred. The signal pins 232, 234, 236, 238, and 240 are duplicated on each of the E-fuses 210 and 212 to allow connection to the corresponding pins on a neighboring E-fuse. The rainbow bridge 230 allows signal lines to be connected between respective pins on the respective sides of the E-fuses 210 and 212 without having to be routed in the areas on the circuit board around the E-fuses 210 and 212. Other pins such as a VCC pin 244, a ground pin 246, and an overcurrent protection value (ILIM) pin 248 are only single pins on the E-fuses 210 and 212. The VCC pin 244 and the ground pin 246 allows voltage to power the E-fuse. The ILIM pin 248 allows the setting of an over current protection value for the E-fuse.

In this example, an external controller such as power controller or baseboard management controller may send a signal to enable the E-fuses 210 and 212 on the enable pin 232. Once the output voltage reaches the value that is set or is within acceptable parameters, a logic high value could be read from the power good pin 238 if the pin 238 is connected to a voltage level higher than 0. In this example, the E-fuse 210 serves as a master device for additional E-fuses such as the E-fuse 212, that take the role of a slave device. The E-fuse 210 and E-fuse 212 share the over temperature value on the over temperature signal pin 240. A power good signal on the PG pin 238 indicates whether these E-fuses reach the set output voltage or are within acceptable parameters. A current reference signal on the current reference pin 236 for all E-fuses is provided to allow the E-fuses to reach a current balance.

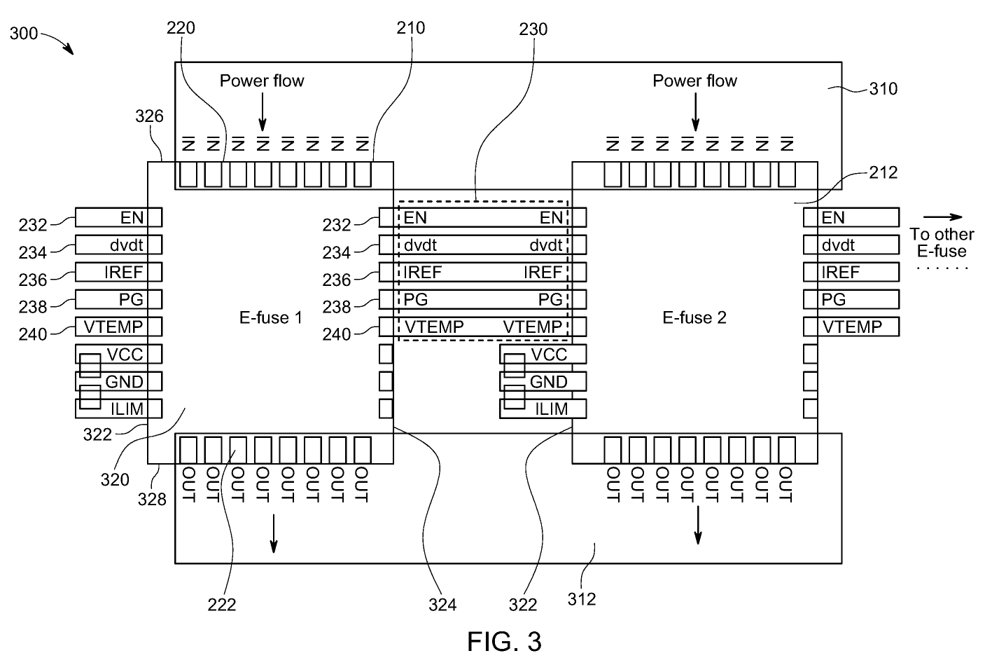

FIG. 3 shows a layout of a printed circuit board 300 that includes the E-fuses 210 and 212 to protect other components from power faults. The E-fuses 210 are connected to a power plane 310 that provides power from a power shelf to the voltage input pins 220 when the printed circuit board 300 is connected to the power shelf. The E-fuses 210 and 212 are also connected to a voltage rail 312 that supplies power to components on the circuit board 300. Thus, the E-fuses 210 and 212 protect the components on the printed circuit board 300 powered by the voltage rail 312 from faults detected in power carried by the power plane 310.

The example E-fuses 210 and 212 each are incorporated in a standard four-sided integrated circuit package 320 shown in FIG. 3. The package 320 has two parallel sides 322 and 324 that each have matching signal pins 232, 234, 236, 238, and 240. The package 320 includes circuits to perform a power management function such as determining faults in the power received on the input pins 220 and cutting off power to the output pins 222. Other input pins 244, 246, and 248 are only located on the side 322 because they aren’t connected to other E-fuses. The pin 248 allows each E-fuse to have an individual current overprotection to be set. Sides 326 and 328 that are parallel to each other and perpendicular to the sides 322 and 324 include the input pins 220 and output pins 222 respectively.

As shown in the layout of the circuit board 300, the power plane 310 may be a substantially rectangular shape with unbroken sides since the plane 310 does not need to be routed to specific input pins on the E-fuses. Further the voltage rail 312 may also be directly connected to the output pins 222 of the E-fuses 210 and 212 and also does not have to have broken sides to be directed to each of the E-fuses 210 and 212.

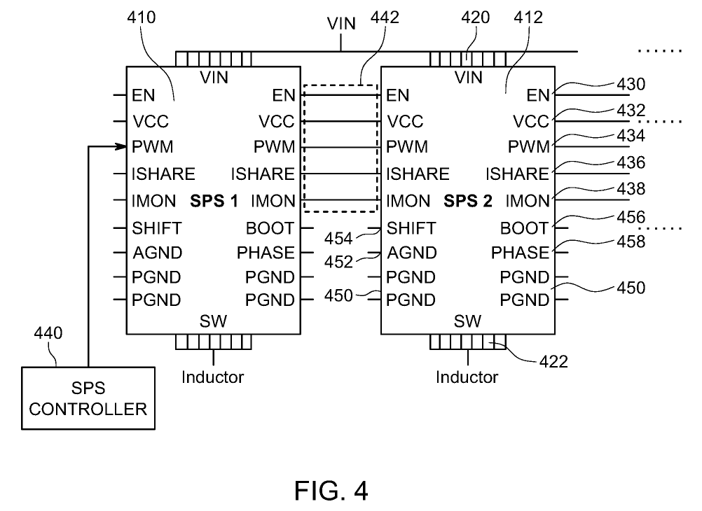

FIG. 4 shows a circuit diagram of a power management assembly that includes SPS chips 410 and 412 in a parallel arrangement. A high voltage/high power source from power supplies on a power shelf is connected to input pins 420. A series of output pins 422 provide regulated voltage from each of the SPS chips 410 and 412. A ground may be connected to different ground input pins on each of the SPS chips 410 and 412.

A set of control signals are generated in a set of control and data signal input pins on the SPS chips 410 and 412. The SPS chips 410 and 412 both have a set of identical signal pins including an enable (EN) pin 430, a VCC pin 432, a control pulse width modulation (PWM) pin 434, a shared sensed current (ISHARE) input 436, and a monitored current (IMON) pin 438. The identical signal pins may each receive an input data or command signal that may be transmitted by the other identical signal pin or transmit an output data or command signal from the SPS chip 410 or 412. An SPS controller 440 sends a PWM signal to the PWM control pins 434 of the SPS chip 410 that may be sent to other SPS chips such as the SPS chip 412 through an example rainbow bridge 442. As will be explained, the PWM signal controls a gate of a buck converter circuit that produces periodic voltage signals from the output pins 422. The rainbow bridge 442 includes a series of interconnections between the same signal pins of the SPS chips 410 and 412. Other pins include several ground pins (PGND) 450, an A Ground (AGND) pin 452, a shift pin 454, a boot pin 456, and a phase pin 458. The ground pins 450 may be tied to a ground for the input power from a power source. The A ground pin 452 may be tied to a ground for the other signal pins such as the shift pin 434. The shift pin 454 allows a value to be input to set a shift of the phase at the output pin 422 and the output current. The boot pin 456 and phase pin 458 with an additional capacitor constitute a bootstrap design to provide the voltage needed to drive the high side MOSFET of the buck converter.

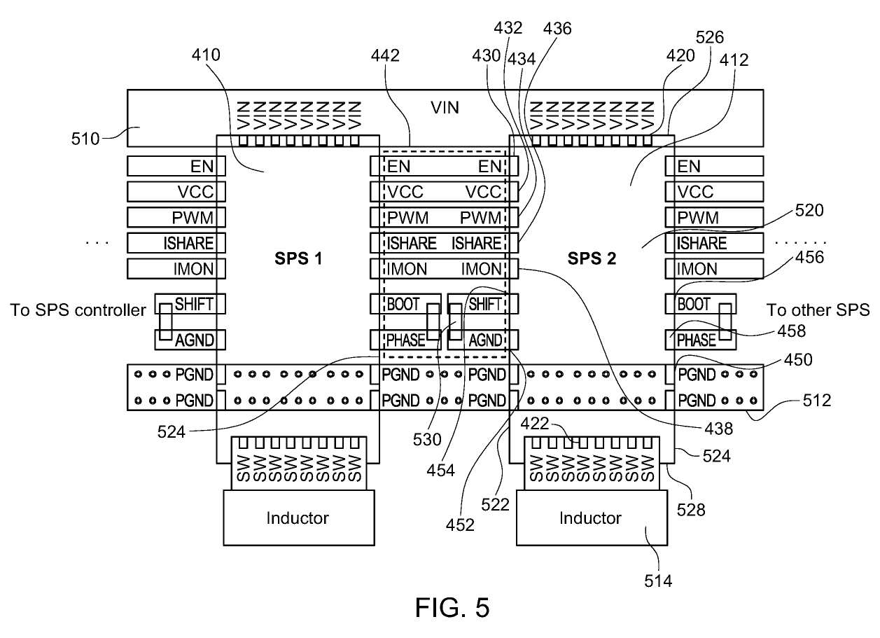

FIG. 5 shows a layout of a printed circuit board 500 that includes the SPS chips 410 and 412 that are SPS devices. The SPS chips 410 and 412 are connected to a power plane 510 that provides power from a power shelf to the voltage input pins 420 when the circuit board 500 is connected to the power shelf. The voltage output pins 422 of the SPS chips 410 and 412 are connected to inductors 514 that are coupled in combination with capacitors that are part of a regulated power circuit. Thus, the SPS chips 410 and 412 protect the components powered by the regulated power circuit from faults detected in power carried by the power plane 510. The SPS chips 410 and 412 also have internal buck converters to generate a pulsed output of a set voltage level based on the PWM control signal from the SPS controller 440 to the regulated power circuit. The regulated power circuit with the inductors 514 and capacitors provide regulated voltage to components on the circuit board 500. The ground pins 450 are connected to a ground strip 512.

The example SPS chips 410 and 412 each are incorporated in a standard four-sided integrated circuit package 520 shown in FIG. 5. In this example, the package 520 holds circuits to perform power management functions such as a buck converter circuit, protection circuits and phase shift circuits. The package 520 has two parallel sides 522 and 524 that each have duplicated signal pins 430, 432, 434, 436 and 438. Other reference pins 452, 454, 456, and 458 are only on one of the sides 522 and 524 as such pins do not need to be tied to the pins of another SPS chip. The package 520 has perpendicular sides 526 and 528 that include the input pins 420 and output pins 422 respectively. In this example, the interconnections of the rainbow bridge 442 connect the pins 430, 432, 434, 436 and 438 between the respective sides 522 and 524 of the SPS chips 410 and 412. The phase pin 458 is tied to the boot pin 456 with a capacitor connected between them. The boot pin 456 and phase pin 458 with an additional capacitor constitute a bootstrap design to provide the voltage needed to drive the high side MOSFET of the buck converter in the SPS chip. As will be explained, a resistor 530 is connected to the shift pin 454 and the A ground pin 452 to set the phase shift for the respective SPS chips 410 and 412.

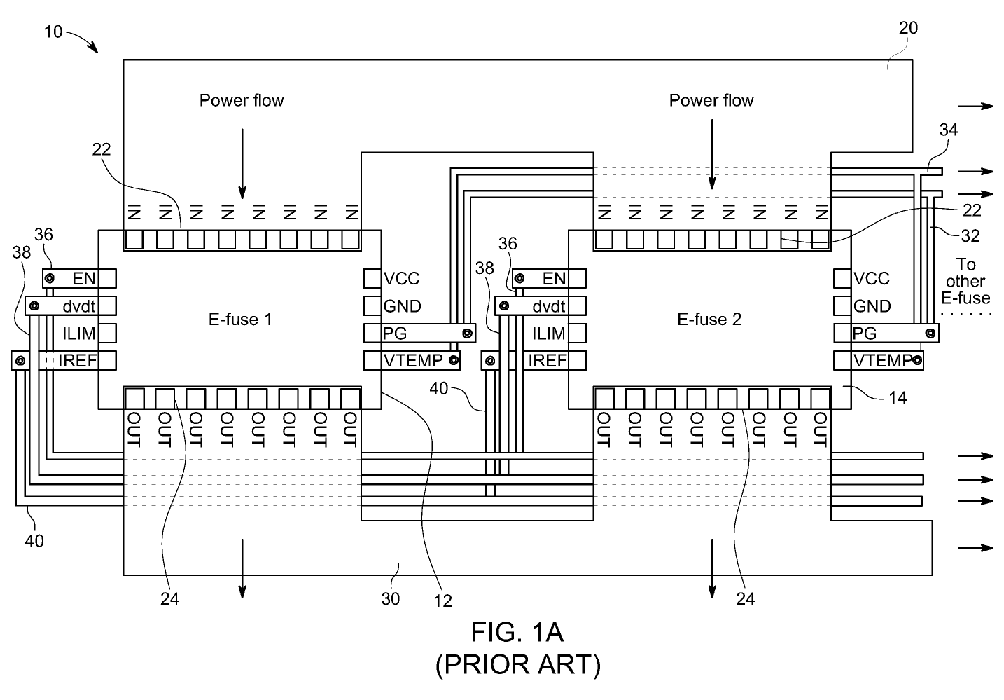

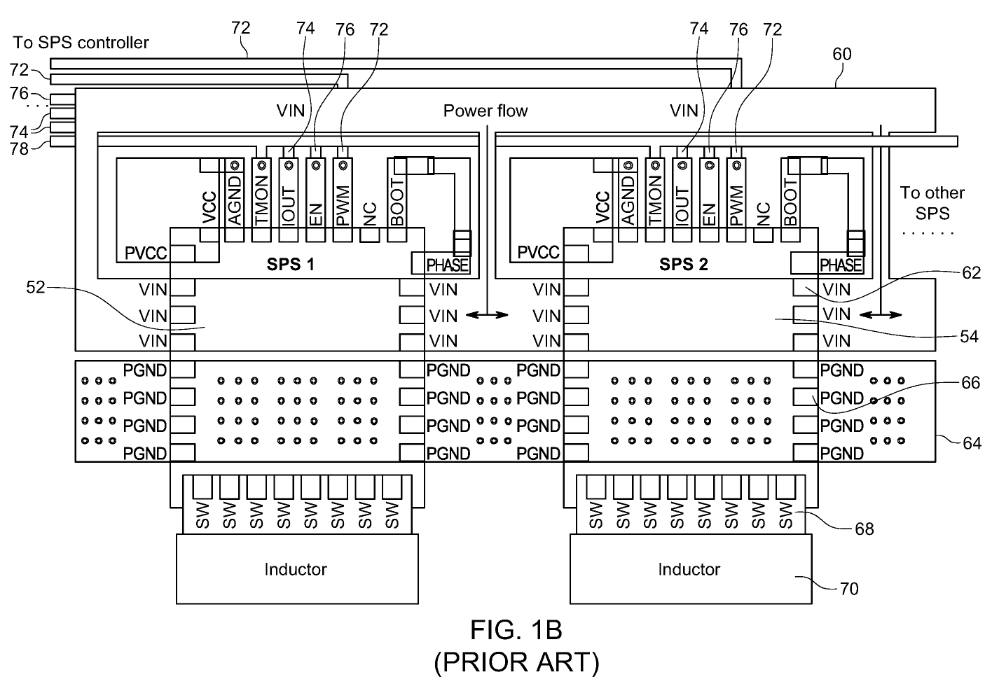

Both the rainbow bridge linked E-fuse arrangement in FIG. 3 and SPS arrangement in FIG. 5 share the same mirrored pinout design on parallel sides of the integrated circuit packages. This arrangement provides major advantages as a result of using the rainbow bridge to interconnect the power management components. The mirrored pinout allows easy interconnection between parallel devices through the rainbow bridge to enable exchange of data or command signals between power management components and/or external controllers. As shown in the layout schemes in FIGS. 3 and 5, all the connected signals are directly sent from one power management component to another via the rainbow bridge. No interconnection routing is required and thus the signal routing lines will not impact, go under, or cut through the high-power plane. Ultra-high current may thus flow into and out of the power management components directly. This arrangement allows for the shape of the power plane to be designed without turns, which leads to better power performance and heat dissipation capability compared with the jagged shape routing of known power planes as shown in FIG. 1A and FIG. 1B. The rainbow bridge arrangement also allows device placement on the top and on the bottom of the printed circuit board, which doubles the possible areas for parallel devices on a printed circuit board size as compared with known pinout designs as shown in FIG. 1A-1B. The design could bring the characteristic of inherent current balance. By applying the rainbow bridge design, a symmetric layout design, power plane design, and routing lines for every device may be provided. The trace and copper impedance will therefore be almost the same for every SPS device, making current evenly flow through each SPS device. Furthermore, no vias are needed for routing interconnection signals, thereby resulting in less crosstalk and noise on signal lines, thus enhancing high circuit precision and noise immunity. Even with limited printed circuit board layers, board designers will not face difficulties when assessing placement and routing. With less vias and the enablement of device placement on the top and bottom of the printed circuit board, the layout may be accomplished with less PCB area thus allowing more flexible placement and routing.

To further minimize the needed circuit board area, a daisy-chained structure concept is incorporated into the rainbow bridge design. Every power management component that is connected to the example rainbow bridge shares the same configuration data or command signal pins and correlated components as much as possible. For instance, the soft-start setting (dvdt) pin 234 in FIG. 3 for all E-fuses are connected and thus all of the E-fuses will read the same value from a soft-start setting input signal and have the same startup time setting, ensuring that all the devices are working synchronously during power on. This concept could be easily extended to other configuration pins as well, making the needed printed circuit board area smaller as extra area for routing traces are not required.

Although the example rainbow bridge design is shown in relation to systems with E-fuses and SPS devices, this design concept could also be applied to other kinds of devices that that are used in parallel and need signals that interconnected with each other with proper modifications.

The example power management systems also incorporate the daisy-chained power management components in FIG. 5 for a multiphase pulse width modulation (PWM) power supply. This reduces the needed PWM signals for multiple SPS devices to only one signal line to the different SPS devices as resistors such as the resistor 530 may be used to set the specific phase shift of each SPS device. Currently, for a known four phase SPS application, four different PWM signals from the SPS controller are required to control the phase of the pulsed voltage signals output from four SPS devices. Each of the output voltage signals have a 90 degrees phase shift with each other. This requires four different PWM signals on different lines routed to the SPS devices and corresponding vias for certain PWM signal lines to cross through the SPS devices. When the number of phases grows, the required routing of signal lines increases. For example, a 16-phase system would require sixteen routing lines to sixteen SPS devices and thus the routing lines are relatively complex and require multiple vias.

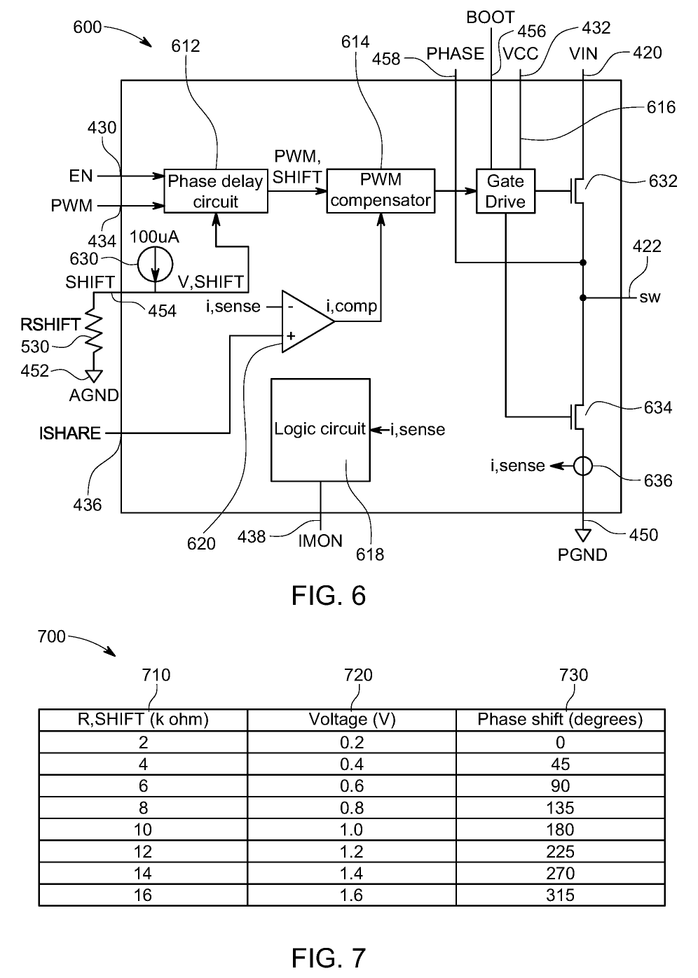

To overcome these drawbacks, a shift pin and a PWM pin are incorporated in the example rainbow bridge based SPS device architecture. This allows multi-phase systems to be controlled with a single PWM signal line as phase shifts may be controlled by the shift pin. The design concept and a key functional control block diagram 600 for the example SPS device are shown in FIG. 6.

The block diagram 600 is an example SPS device such as the SPS chip 410 in FIG. 4. The SPS device in FIG. 6 is a four-phase buck converter circuit with a duty cycle of 0.25 for simplicity of explanation. The buck converter circuit includes a high side MOSFET 632, a low side MOSFET 634, and a gate drive 616 to drive the MOSFETs 632 and 634. The buck converter circuit also includes a PWM compensator 614, a phase delay circuit 612 as well as an internal current source 630. These principles may be applied to higher numbers of phases such as 8-phase or 16-phase systems.

The phase delay circuit 612 that produces a shifted PWM signal to a PWM compensator 614. The current source 630 is coupled to the shift line to the PWM compensator 614. The PWM compensator 614 outputs a shifted phase signal to the gate drive 616 that outputs signals to connect the power from the voltage input pin 420. A logic circuit 618 is coupled to the IMON pin 438 to read the current value sensed at a current sensing node 636 and provide the output at the current monitoring IMON pin 438. In this example, the enable pin 430 and the PWM pin 434 are coupled to the phase delay circuit 612. When an enable signal is received by the enable pin 430, the phase delay circuit 612 is activated. The PWM pin 434 receives a PWM signal from the SPS controller 440 in FIG. 4. The phase delay circuit 612 shifts the phase of the PWM signal according to a shift input to provide the phase shift of the PWM signal sent to the PWM compensator 614. The phase shift is generated by the voltage drop from the resistor 530 that is tied to the shift pin 454 and the A ground pin 452.

The power from the voltage input pin 420 provides power that may be activated by the gate drive 616 closing the MOSFETs 632 and 634, according to the shifted PWM signal. The PWM signal from the controller creates voltage pulse output from the gate drive 616 with a .25 duty cycle. The closed MOSFETs 632 and 634 connect the voltage input pins 420 to the ground pins 450 to output voltage on the output pin 422. Thus, the output from the output pin 422 is a pulse having a maximum amplitude of the voltage on the input voltage pin 420. The current sensing node 636 is coupled between the ground pin 450 and the switch 634. The output of the current sensing node 636 is coupled to the logic circuit 618 and one input of the operational amplifier 620. The gate drive 616 is tied to the boot pin 456, which is tied to the phase pin 458 through an external capacitor. The boot pin 456 and phase pin 458 with an external capacitor constitute a bootstrap design to provide the voltage needed to drive the high side MOSFET 632 of the buck converter circuit. The gate drive 616 is powered by the voltage coupled to the VCC pin 432.

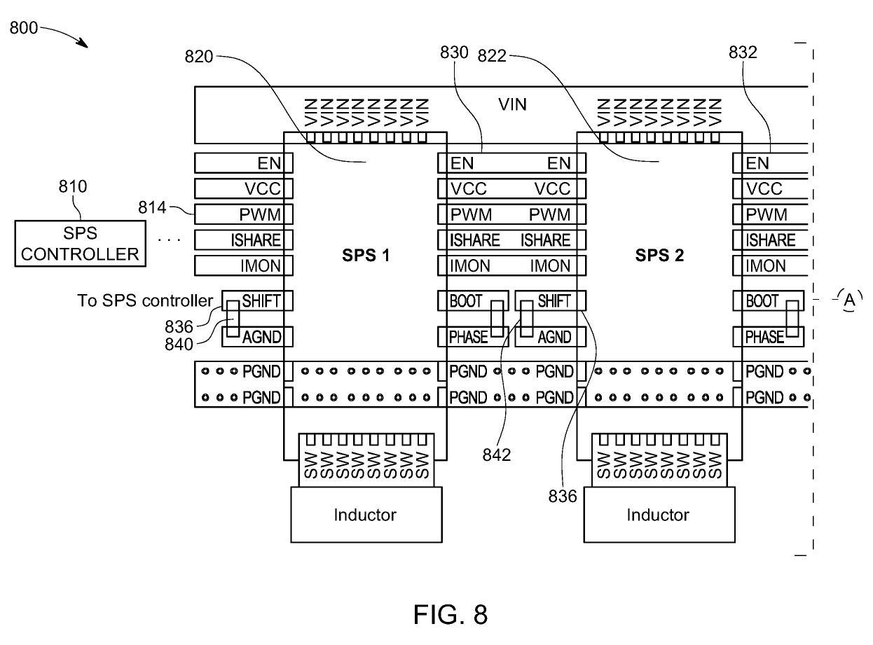

By connecting resistors with different values, a designed internal current source such as the current source 630 will be implemented to build up a specific voltage level on the shift pin for each of the SPS devices. Specific voltage levels could be defined and matched with specific phase shift degrees as shown in a table 700 in FIG. 7. In this example, the resistors and corresponding voltages are designed for a four phase or eight phase system, but other numbers of phases could use this approach. The table 700 includes a resistor value column 710, a voltage output column 720, and a phase shift column 722. Thus, different resistor values for the resistor 530 in column 710 will produce different voltages that may be input to the shift pin 454 as shown in column 720. The different voltages result in different phase shift degrees in column 740.

As explained above, the PWM signal sent from the SPS controller 440 in FIG. 4 will be taken as the reference signal. The phase delay circuit 612 performs the phase delay function. A specific voltage value is read from the shift pin 454 according to the table 700 in FIG. 7. The phase delay circuit 612 will produce a specific degree phase shift to the received PWM signal.

Designers have the flexibility to adjust and design different voltage and phase shift relationships by adjusting the internal current source or modifying the phase delay circuit. The duty cycle of the shared input PWM signal will be determined and adjusted by the SPS controller 440 according to the instantaneous output voltage that is fed back to the controller from the a feedback output (not shown). After passing through the phase delay circuit 612, the PWM signal will be shifted with specific phase degrees according to the value on the shift pin 454. In the example by connecting 2kohm, 6kohm, 10kohm and 14kohm resistors to the shift pins of four different SPS devices using the table 700 in FIG. 7, a 90 degrees phase shift for each SPS could be achieved.

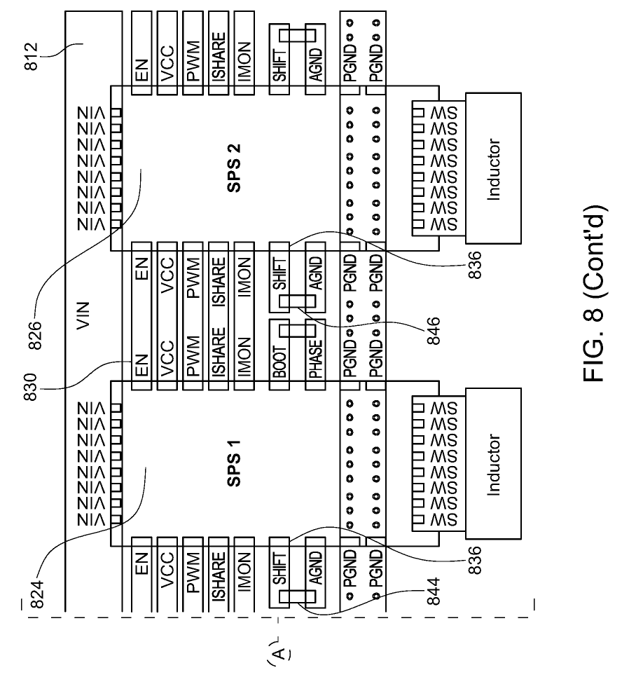

FIG. 8 shows an example block diagram of a four-phase power management system 800 using resistor values from the table 700. The power management system 800 includes a SPS controller 810. A power plane 812 provides power from a power shelf. The SPS controller 810 outputs a single PWM signal on a PWM signal line 814 for controlling the pulse frequency of output voltage signals. Four SPS devices 820, 822, 824, and 826 are each interconnected via rainbow bridges 830, 832 and 834. Each of the SPS devices 820, 822, 824, and 826 have a phase pin 836 that is tied to respective resistors 840, 842, 844, and 846. Thus, each of the SPS devices 820, 822, 824, and 826 output pulsed voltage signals on the inductor/capacitor regulation circuits at different phases driven by the PWM signal from the PWM controller 810.

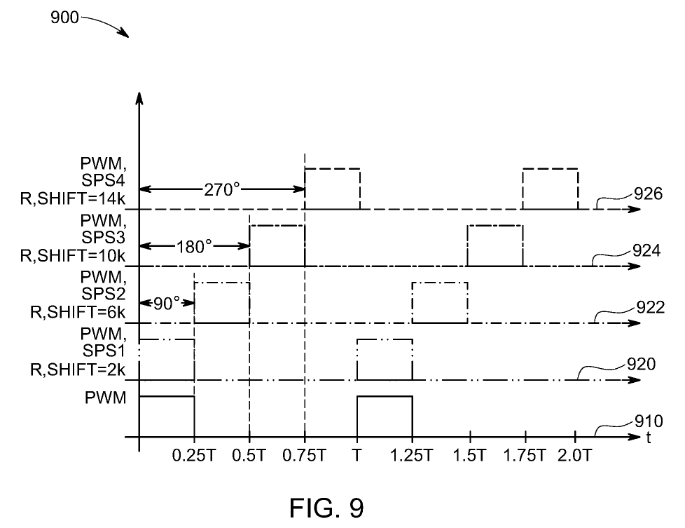

FIG. 9 shows a voltage trace diagram 900 of the PWM signals for the four different SPS devices that each have a 90 degree phase shift. The PWM control signal from the PWM controller 810 is shown as a pulsed voltage trace 910. The pulse in this example is a 0.25 duty cycle. The resistor 840 for the first SPS device 820 is at 2k and thus no phase shift occurs as shown by a trace 920. The resistor 842 for the second SPS device 822 is at 6k and thus a phase shift of 90 degrees is produced as shown by a trace 922. The resistor 844 for the third SPS device 824 is at 10k and thus a phase shift of 180 degrees is produced as shown by a trace 924. The resistor 846 for the fourth SPS device 826 is at 14k and thus a phase shift of 270 degrees is produced as shown by a trace 926.

Current balancing is achieved by the operational amplifier 620 and the current feedback compensator 614. One input of the operational amplifier 620 is coupled to the current sensing node 636. The other input of the operational amplifier 620 is tied to the Ishare pin 436. The operational amplifier 620 compares the current sensing value in the device from the current sensing node 636 with the current value shared by all devices as read from the shared current pin 436. This provides the information of how much current that one SPS device needs to transfer to reach balancing. In this example, if the sensing current value is lower than the reading value from the pin 436, then the operational amplifier 620 will output a positive value to add into the PWM compensator 614, making the PWM duty cycle higher, which leads to a higher current. With all these signals, the PWM compensator 614 in each SPS device determines the finalized gate signal to the gate drive 616. This ensures safe and proper operation of a multiphase voltage regulator. This design concept could be extended to 16 phases or even more if needed. This design concept has the potential to become more beneficial as the number of phases required increases.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A power management component for receiving power from a power source and performing a power management function, the power management component comprising:
a first side including an input pin connectable to the power source;
a second side parallel to the first side including an output pin connectable to a power rail on a circuit board;
a power management function circuit coupled between the input pin and the output pin; and
a pair of sides perpendicular to the first side, each of the pair of sides including at least one identical signal pin, the identical signal pin being configured to receive an input signal that may be transmitted by the other identical signal pin or transmit an output signal from the power management component.

2. The power management component of claim 1, wherein the power management component is an E-fuse and wherein the power management function circuit cuts off power to the output pin when a fault is detected in the power source.

3. The power management component of claim 2, wherein the at least one identical signal pin is one of a power good signal pin, an over-temperature signal pin, an enable signal pin, a soft-start setting pin, or a current reference signal pin.

4. The power management component of claim 1, wherein the power management component is a smart power stage (SPS) device wherein the power management function circuit is a buck converter outputting a pulsed voltage signal.

5. The power management component of claim 4, wherein the at least one identical signal pin is one of a sensed current signal pin, an enable signal pin, or a sensed temperature pin.

6. The power management component of claim 4, wherein the at least one identical signal pin receives a pulse width modulation (PWM) signal driving the buck converter.

7. The power management component of claim 6, further comprising a phase shift input pin connectable to a resistor, wherein a value of the resistor determines a phase of the PWM signal provided to the buck converter.

8. The power management component of claim 1, wherein the at least one identical signal pin is one of a plurality of identical signal pins, each connectable to a rainbow bridge interconnection coupling each of the plurality of signal pins to a corresponding signal pin of another power management device, the another power management component having an input pin connectable to the power supply.

9. A printed circuit board comprising:
a power plane connectable to a power shelf having a power supply;
a first power management component having a first side including an input pin connectable to the power plane; a second side parallel to the first side including an output pin; a power management function circuit coupled between the input pin and the output pin; and a pair of sides perpendicular to the first side, each of the pair of sides including at least one identical signal pin;
a second power management component having a first side including an input pin connectable to the power plane; a second side parallel to the first side including an output pin; a power management function circuit coupled between the input pin and the output pin; and a pair of sides perpendicular to the first side, each of the pair of sides including at least one identical signal pin; and
a first rainbow bridge directly coupling one of the identical signal pins of the first power management component to one of the identical signal pins of the second power management component.

10. The printed circuit board of claim 9, wherein the power plane has a substantially rectangular shape.

11. The printed circuit board of claim 9, wherein the first and second power management components are E-fuses and wherein the power management function circuit cuts off power to the output pin when a fault is detected in the power plane.

12. The printed circuit board of claim 11, wherein the at least one identical signal pin is one of a power good signal pin, an over-temperature signal pin, an enable signal pin, a soft-start setting pin, or a current reference signal pin.

13. The printed circuit board of claim 9, wherein the first and second power management components are smart power stage (SPS) devices and wherein the power management function circuit is a buck converter outputting a pulsed voltage signal.

14. The printed circuit board of claim 13, wherein the at least one identical signal pin is one of a sensed current signal pin, an enable signal pin, or a sensed temperature pin.

15. The printed circuit board of claim 13, further comprising an inductor and capacitor regulated voltage circuit coupled to the output pins of the first and second power management components to provide regulated voltage to components on the printed circuit board.

16. The printed circuit board of claim 13, further comprising a power management controller including a pulse width modulation (PWM) signal output coupled to the identical signal pin of the first power management component, wherein the PWM signal drives the buck converters of the first and second power management components.

17. The printed circuit board of claim 16, further comprising:
a first resistor coupled to a phase shift pin on the first power management component, wherein a value of the first resistor determines a first phase of the PWM signal provided to the buck converter of the first power management component; and
a second resistor coupled to a phase shift pin on the second power management component, wherein a value of the second resistor determines a second phase of the PWM signal provided to the buck converter of the second power management component.

18. The printed circuit board of claim 9, further comprising:
a third power management component having a first side including an input pin connectable to the power plane; a second side parallel to the first side including an output pin; a power management function circuit coupled between the input pin and the output pin; and a pair of sides perpendicular to the first side, each of the pair of sides including at least one identical signal pin; and
a second rainbow bridge directly coupling one of the identical signal pins of the second power management component to one of the identical signal pins of the third power management component.

19. A smart power stage (SPS) device comprising:
an integrated circuit package having a first side, an opposite second side, and a pair of sides perpendicular to the first side;
a voltage input pin on the first side connectable to a power source;
an output pin on the opposite second side;
a buck converter coupled between the voltage input pin and the output pin to provide a pulsed voltage signal on the output pin;
a first pulse width modulation (PWM) signal pin on one of the pair of sides; and
a second PWM signal pin on the other of the pair of sides, wherein a PWM signal received on the first PWM signal pin is output by the second PWM signal pin and drives the buck converter.

20. The SPS device of claim 19, further comprising a phase shift pin connectable to a resistor to shift the phase of the pulsed voltage signal provided by the buck converter.
